(19) United States
(12) Patent Application Publication
(10) Pub. No.: US 2015/0357798 A1
(43) Pub. Date: Dec. 10, 2015

(54) INTEGRATED BUS DUCT AND UPS SYSTEMS

(71) Applicant: Eaton Corporation, Cleveland, OH (US)

(72) Inventors: Chris Arthur Loeffler, Wake Forest, NC (US); George Arthur Navarro, Raleigh, NC (US)

(21) Appl. No.: 14/296,771

(22) Filed: Jun. 5, 2014

(51) Int. Cl. H02B 1/20; H05K 7/20; H02J 9/06

(52) U.S. Cl. CPC H02B 1/20; H02J 9/061; H05K 7/20572

(57) ABSTRACT

A system includes electrical equipment racks arranged in at least one row and including at least one electrical equipment rack having at least one UPS therein. The system further includes a bus duct assembly including an elongate housing extending along the at least one row and having electrical bus bars therein electrically coupled to the electrical equipment racks and including at least one AC bus bar coupled to an output of the at least one UPS and at least one DC bus bar coupled to an input of the at least one UPS. The bus duct assembly may further include at least one cooling air passage in communication with airspaces of the electrical equipment racks.

### BACKGROUND

The inventive subject matter relates to power distribution apparatus and methods and, more particularly, to uninterruptible power supply (UPS) apparatus and methods.

UPS systems are commonly used in installations such as data centers, medical centers and industrial facilities. UPS systems are typically used in such installations to maintain power quality and provide backup power in the event of failure of the primary utility supply.

Power distribution systems in installations such as data centers may be implemented in a number of different ways. In some facilities, for example, power distribution equipment such as UPSs, step-down transformers and switchgear may be housed in a dedicated equipment room. In some installations, power may be distributed from this equipment room to wall-mounted panelboards located in a separate room near racks that house information technology (IT) equipment (e.g., computer and/or networking equipment), and branch circuit cabling from the panelboards to the IT racks may be run overhead in trays or under raised flooring. In some data centers, power may be distributed from UPSs to rack-like power distribution units (PDUs) that are distributed among the IT racks, and branch circuit cables from the PDUs to the IT racks may be run in overhead trays or run under a raised floor.

Some data centers employ modular busway that is fed from a main equipment room through subfeed panels. The busway may be suspended above IT racks or installed beneath computer equipment racks in raised floor systems. The IT racks may be connected to the busway via modular bus plug units that serve as power taps. Such a bus plug unit may include a circuit breaker to protect the circuit running from the busway to the IT rack.

Some data center power systems use arrangements in which UPSs are distributed among computer equipment, rather than being housed in a main electrical equipment room. For example, U.S. Pat. No. 8,173,898 to Rasmussen et al. describes system in which UPSs are housed in racks that are distributed among IT racks and power is distributed from the UPSs to the IT racks using cabling that runs over the top of the racks. Still other data center configurations may use UPSs that are housed in the same racks as the IT equipment that they serve.

### SUMMARY

Some embodiments of the inventive subject matter provide a system including electrical equipment racks arranged in at least one row, the electrical equipment racks including at least one electrical equipment rack having at least one UPS therein. The system further includes a bus duct assembly including an elongate housing extending along the at least one row and having electrical bus bars therein electrically coupled to the electrical equipment racks. The electrical bus bars include at least one AC bus bar coupled to an output of the at least one UPS and at least one DC bus bar coupled to an input of the at least one UPS. The electrical equipment racks may further include at least one electrical equipment rack having at least one energy storage device therein coupled to the at least one DC bus bar,

The at least one AC bus bar may include at least one first AC bus bar and the electrical bus bars may further include at least one second AC bus bar electrically coupled to an input of the at least one UPS. The electrical equipment racks may include at least one electrical equipment rack having a static switch therein configured to couple the at least one first AC bus bar to the at least one second AC bus bar. The system may also include at least one switchgear unit mechanically attached to and supported by the bus duct housing and configured to couple the output of the at least one UPS to the at least one first AC bus bar. The system may further include at least one switchgear unit mechanically attached to and supported by the bus duct housing and configured to couple the at least one second AC bus bar to an AC power source. In further embodiments, the bus duct housing may have at least one air passage defined therein in fluid communication with airspaces within the electrical equipment racks and configured to support air movement therefrom.

Further embodiments of the inventive subject matter provide a system including electrical equipment racks arranged in at least one row and a bus duct and cooling assembly including an elongate housing extending along the at least one row and having at least one air passage in fluid communication with airspaces within the electrical equipment racks and configured to support air movement therefrom. The bus duct and cooling assembly further includes electrical bus bars in the housing and electrically coupled to the electrical equipment racks. The electrical bus bars may be positioned inside the at least one air passage and/or positioned in at least one chamber of the housing separate from the at least one air passage. The system may further include at least one air moving device, such as a fan, in fluid communication with the at least one air passage and configured to cause air movement from the airspaces of the equipment racks through the at least one air passage.

In some embodiments, the bus bars may include at least one AC bus bar and at least one DC bus bar and the electrical equipment racks may include at least one electrical equipment rack containing at least one UPS electrically coupled to the at least one AC bus bar and to the at least one DC bus bar. The electrical equipment racks may further include at least one electrical equipment rack containing at least one energy storage device coupled to the at least one DC bus bar.

Additional embodiments of the inventive subject matter provide a system including electrical equipment racks, a bus duct including an elongate housing and electrical bus bars including at least one AC bus bar and at least one DC bus bar in the housing, and at least one UPS mechanically attached to and supported by the housing and electrically coupled to the at least one AC bus bar, the at least one DC bus bar and at least one of the electrical equipment racks. The electrical equipment racks may be arranged in at least one row and the bus duct may extend longitudinally along the at least one row. The system may further include at least one energy storage device coupled to the at least one DC bus bar. In some embodiments, the system may include at least one static switch unit mechanically attached the housing and electrically coupled to the at least one AC bus bar and configured to couple the at least one AC bus bar to an AC power source.

In some embodiments, the at least one UPS may be configured as a bus plug unit pluggably coupled to the at least one AC bus bar and the at least one DC bus bar. The at least one UPS may be coupled to the at least one of the electrical equipment racks using a flexible cable. The at least one UPS may include, for example, a double conversion UPS and/or a standby UPS.

Still further embodiments provide a bus duct and cooling assembly including an elongate housing having at least one air passage configured to be coupled in fluid communication with airspaces within electrical equipment racks of a row of electrical equipment racks to support air movement therefrom and electrical bus bars in the housing and electrically coupled to the electrical equipment racks. The electrical bus bars may include at least one AC bus bar and at least one DC bus bar.

Further embodiments of the inventive subject matter provide an assembly including a housing configured to be mechanically mounted on a bus duct, a UPS in the housing, at least one first contact coupled to an DC input of the UPS and configured to be connected to at least one DC bus bar of the bus duct, and at least one second contact coupled to an AC input of the UPS and configured to be connected to at least one AC bus bar of the bus duct.

### BRIEF DESCRIPTION OF THE DRAWINGS

FIGS. 1 and 2 illustrate a UPS power distribution system incorporating a bus duct with AC and DC buses according to some embodiments of the inventive subject matter.

FIG. 3 is a cutaway view of the bus duct of FIGS. 1 and 2.

FIGS. 4 and 5 illustrate a UPS power distribution system according to further embodiments of the inventive subject matter.

FIG. 6 illustrates a UPS power distribution system incorporating a bus duct and cooling system according to some embodiments of the inventive subject matter.

FIG. 7 is a cutaway view of the bus duct and cooling system of FIG. 6.

FIG. 8 illustrates a UPS power distribution system with bus duct mounted switch gear according to some embodiments of the inventive subject matter.

FIG. 9 illustrates a power distribution system using UPS bus plug units according to some embodiments of the inventive subject matter.

FIG. 10 is a partial cutaway view of a bus duct and UPS bus plug unit of FIG. 9.

FIGS. 11-13 are schematic diagrams illustrating UPS bus plug units with various different UPS architectures according to some embodiments of the inventive subject matter.

FIG. 14 illustrates a power distribution system with varied UPS bus plug units according to some embodiments of the inventive subject matter.

### DETAILED DESCRIPTION

Specific exemplary embodiments of the inventive subject matter now will be described with reference to the accompanying drawings. This inventive subject matter may, however, be embodied in many different forms and should not be construed as limited to the embodiments set forth herein; rather, these embodiments are provided so that this disclosure will be thorough and complete, and will fully convey the scope of the inventive subject matter to those skilled in the art. In the drawings, like numbers refer to like elements. It will be understood that when an element is referred to as being “connected” or “coupled” to another element, it can be directly connected or coupled to the other element or intervening elements may be present. As used herein the term “and/or” includes any and all combinations of one or more of the associated listed items.

The terminology used herein is for the purpose of describing particular embodiments only and is not intended to be limiting of the inventive subject matter. As used herein, the singular forms “a”, “an” and “the” are intended to include the plural forms as well, unless expressly stated otherwise. It will be further understood that the terms “includes,” “comprises,” “including” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive subject matter belongs. It will be further understood that terms, such as those defined in commonly used dictionaries, should be interpreted as having a meaning that is consistent with their meaning in the context of the specification and the relevant art and will not be interpreted in an idealized or overly formal sense unless expressly so defined herein.

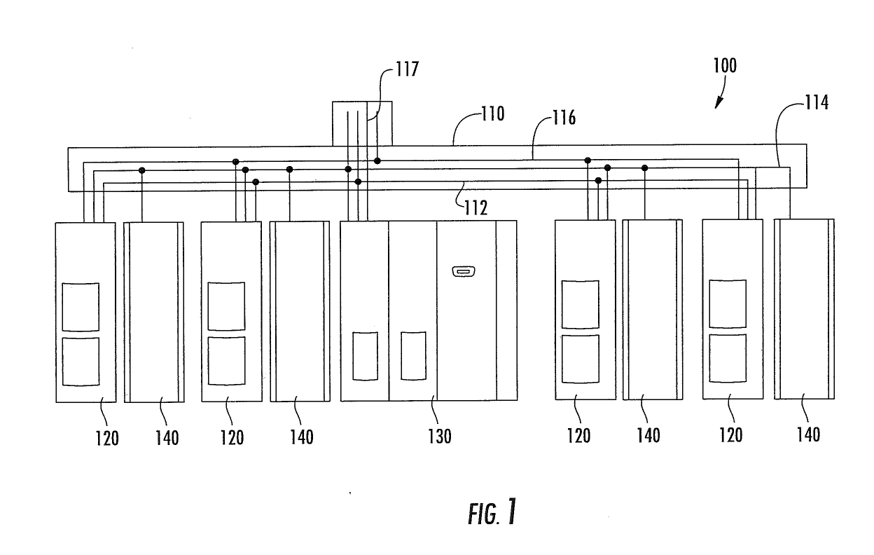

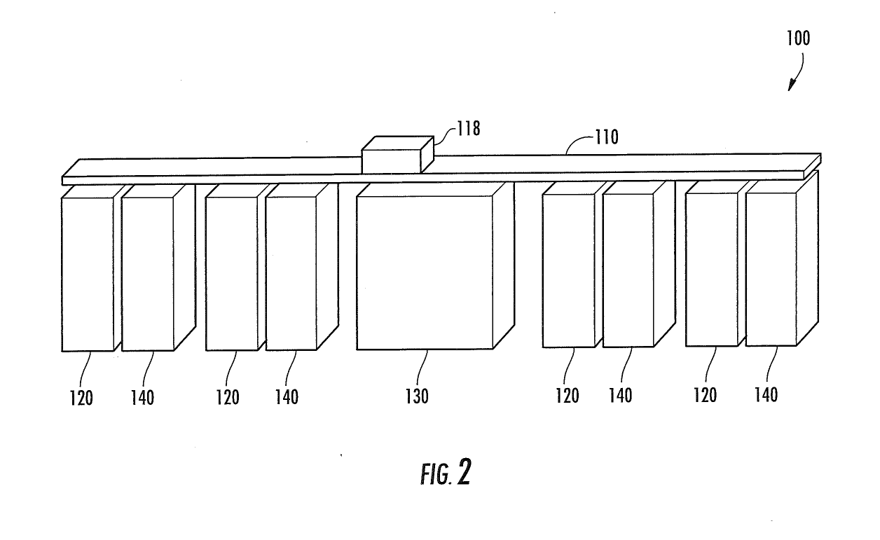

FIGS. 1 and 2 illustrate a system 100 according to some embodiments of the inventive subject matter. The system 100 includes a row of electrical equipment racks, here shown as including UPS racks 120, a bypass rack 130 and information technology equipment (IT) racks 140. As used herein, an “electrical equipment rack” may include racks, cabinets and similar structures that house electrical equipment including, but not limited to, IT equipment, UPSs, energy storage (e.g., batteries, flywheels, fuel cells, etc.), switchgear, and the like. In some embodiments, the UPS racks 120 may be, for example, dedicated racks that provide UPS functionality, such as the double-conversion uninterruptible power modules (UPMs) employed in the Eaton Power Xpert™ 9395 Backup Power System described in Product Brochure, Power Xpert™ 9395 UPS (2013). The bypass rack 130 may include equipment that provides a static bypass switch functionality, such as the integrated system bypass module (ISBM) included in the aforementioned Eaton Power Xpert™ 9395 Backup Power System. The IT racks 140 may include various types of computer and networking equipment, such as servers, routers, hubs, switches and the like.

A busway 110 is configured to provide power interconnection among the racks 120, 130, 140. As shown, the busway 110 includes an AC input bus 112, an AC output bus 114, and a DC bus 116, The AC input bus 112 may be coupled to an external AC source (e.g., a utility source, local generator, or the like, via intermediate components such as switchgear and transformers). The DC bus 116 may be coupled to a DC source, such as a battery bank, flywheel storage device, fuel cell or the like. The AC and DC sources may be coupled to the buses of the busway 110 in a variety of different ways.

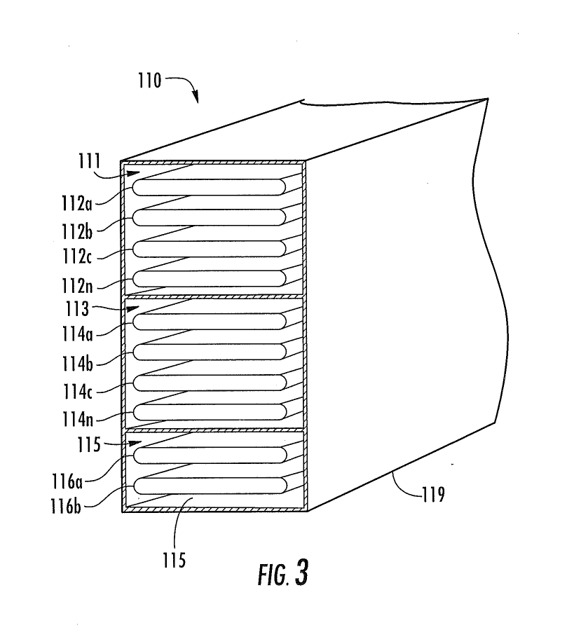

The busway 110 may include a plurality of bus bars contained within an elongate housing that runs along the row of equipment racks 120, 130, 140. For example, in a three-phase application as shown in FIG. 3, the AC input bus 112 may include phase bus bars 112a, 112b, 112c and a neutral bus bar 112n. Similarly, the AC output bus 114 may include phase bus bars 114a, 114b, 114c and a neutral bus bar 114n. The DC bus 116 may include bus bars 116a, 116b. The bus bars 112a-n, 114a-n, 116a-b are contained within a housing 119. For example, as shown, the bus bars 112a-n, 114a-n, 116a-b of the respective buses 112, 114, 116 maybe contained within respective compartments or channels 111, 113, 115 of the housing 119.

Referring again to FIG. 1, the UPS racks 120 are each connected to the AC input bus 112, the AC output bus 114, and the DC bus 116. In particular, AC inputs of the UPS racks are coupled to the AC input bus 112, DC inputs of the UPS racks 120 are coupled to the DC bus 116 and AC outputs of the UPS racks 120 are coupled to the AC output bus 114. The bypass rack 130 is coupled to the AC input bus 112, the AC output bus 114 and to a bypass AC source 117, e.g., a utility or other AC source passing through a different path than the AC source coupled to the AC input bus 112. The bypass source 117 may be provided to the bypass rack 130 via the busway 110 or via a separate path.

The UPS racks 120 act to provide uninterruptible power to the IT racks 140 via the AC output bus 114. In particular, under normal conditions, the UPS racks 120 may power the AC output bus 114 in parallel using power received from the AC input bus 114, and may maintain power to the IT racks 140 when the AC source coupled to the AC input bus 114 fails using power received from a battery or other energy storage device connected to the DC bus 116. The UPS racks 120 may have any of a variety of different UPS architectures, such as double-conversion or bypass architectures. The bypass rack 130 may bypass the UPS racks 120 in the event of failure thereof by coupling the bypass source 117 directly to the AC output bus 114.

FIGS. 1 and 2 show a system in which the busway 110 is positioned above the equipment racks 120, 130, 140. In such arrangements, the busway 110 may be suspended above the racks 120, 130, 140 from a ceiling or other structure. In further embodiments, the busway 110 may be configured to be supported by the racks 120, 130, 140 using standoffs or other features attached to the racks 120, 130, 140. In other embodiments, the busway 110 may have a different positional relationship with respect to the racks 120, 130, 140. For example, the busway 110 may be positioned adjacent rear faces of the racks 120, 130, 140 or underneath the racks 120, 130, 140 beneath a raised floor. Connection of the racks 120, 130, 140 may be made using, for example, cables connected to the bus bars of the busway 110 using, for example, bolt-on and/or plug-in connections.

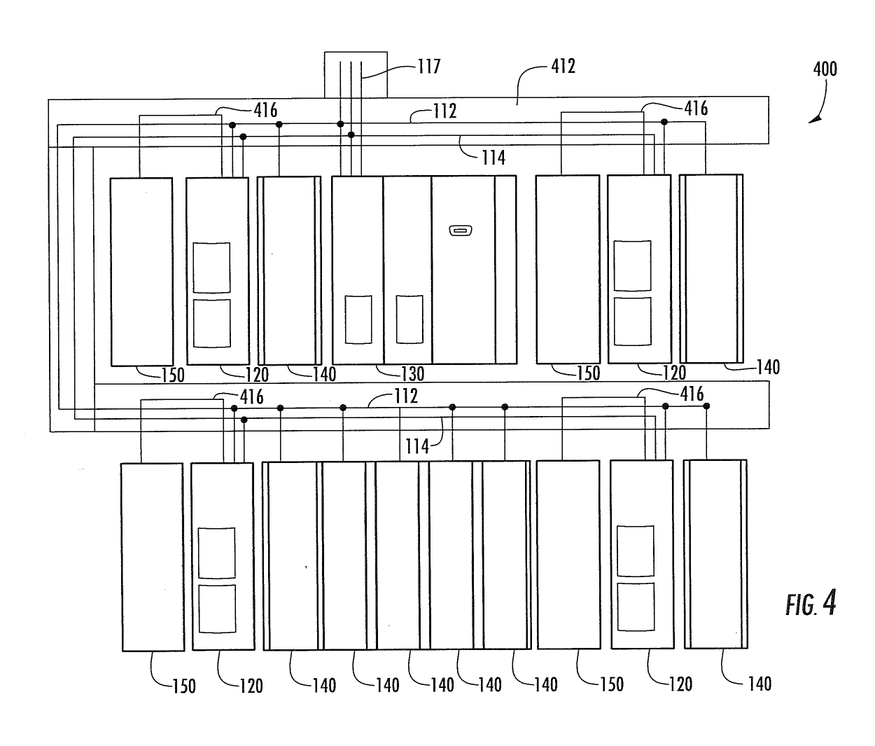

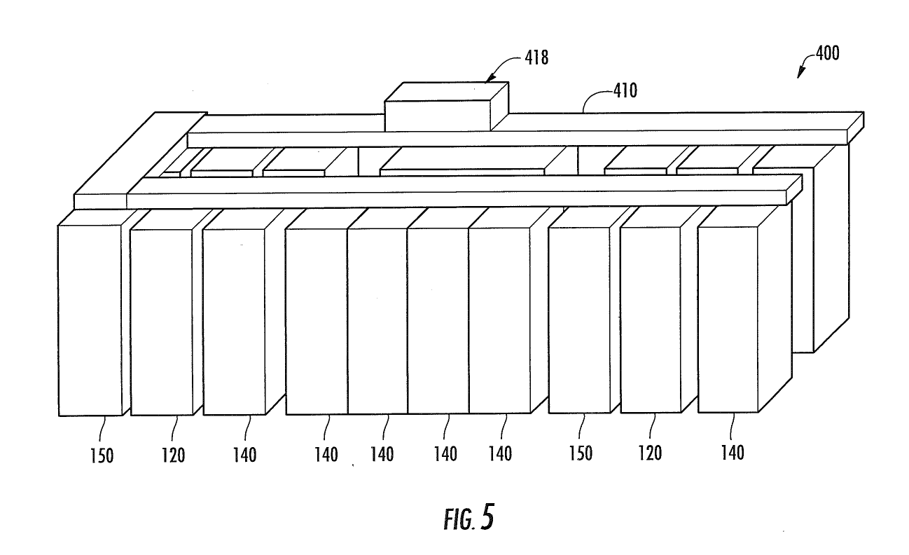

While FIGS. 1 and 2 illustrate a busway 110 running along a single row of racks, it will be appreciated that other arrangements may be used. For example, FIGS. 4 and 5 show a U-shaped multi-row arrangement with a corresponding busway 410 that may be used to support a “hot isle/cold isle” configuration. As further shown in FIG. 4, rather than providing a single DC bus coupled to an external DC source as shown in FIG. 1, the busway 410 may include multiple DC bus segments 416 which are used to interconnect respective energy storage (e.g., battery) racks 150 to respective UPS racks 120.

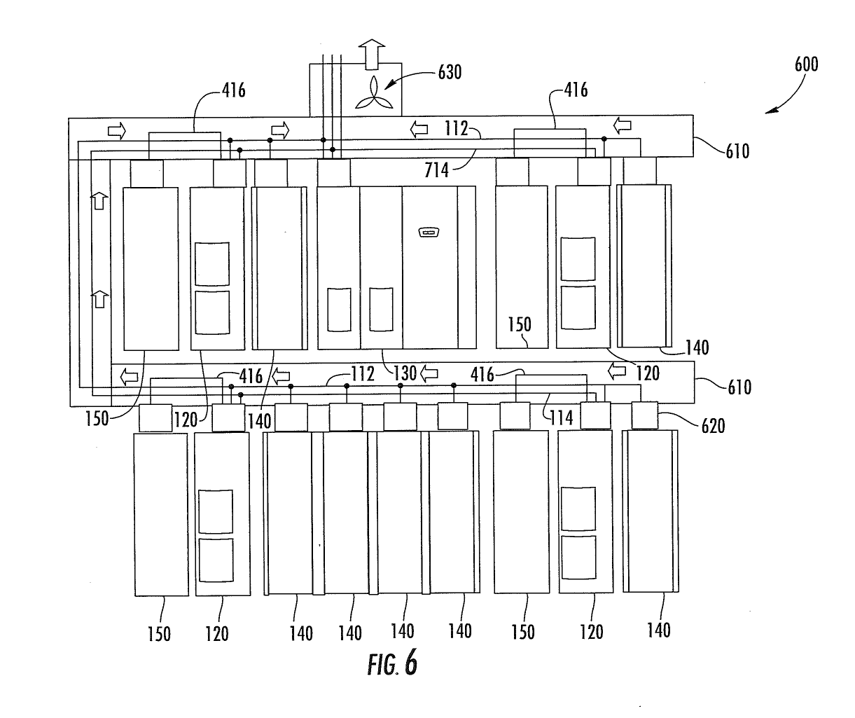

According to further embodiments, a multi-bus busway along the lines described above may also be used to support cooling of equipment racks. Referring to FIG. 6, a system 600 may include UPS racks 120, bypass switch racks 130, IT racks 140 and energy storage racks 150 coupled to a busway 610. The busway 610 includes an AC input bus 112, an AC output bus 114 and DC buses 416, similar to the arrangement shown in FIG. 4. The busway 610, however, is further configured to provide at least one air passage in fluid communication with airspaces of the racks 120, 130, 140, 150 to support cooling thereof. For example, the busway 610 may be configured to support movement of air out of the racks 120, 130, 140, 150 and through the busway 610 using an air moving device, such as a fan 630. It will be appreciated that the air passage of the busway 610 may be connected to an external exhaust system and that code requirements may dictate that such an exhaust system be segregated from other HVAC systems.

The AC input bus 112, the AC output bus 114 and/or the DC bus 416 may be contained with the air passage, e.g., air may pass through chambers that contain bus bars of the buses, such as the chambers 111, 113, 115 shown in FIG. 3. In some embodiments, however, the busway 610 may include an air passage segregated from the electrical buses. For example, FIG. 7 shows a busway 610 including an elongate housing 619 with respective chambers 611, 613, 615 that contain respect groups of bus bars 112a-n, 114a-n, 116a-n, along with a separately air passage 617 configured to provide cooling air transport. As shown in FIG, 6, individual air passages (e.g., ducts) 620 may be in fluid communication with airspaces of the respective racks 120, 130, 140, 150 and fluidically couple the respective airspaces to air passage in the busway 610. Electrical conductors connecting the racks 120, 130, 140, 150 to the busway 610 may pass through the passages connecting the racks 120, 130, 140, 150 to the busway 610, or may pass outside of the air passages. It will be appreciated that all of the equipment racks may be fluidically coupled to the air passage in the busway 160 or, in some embodiments, only selected ones of the equipment racks may be connected to the air passage in the busway 610.

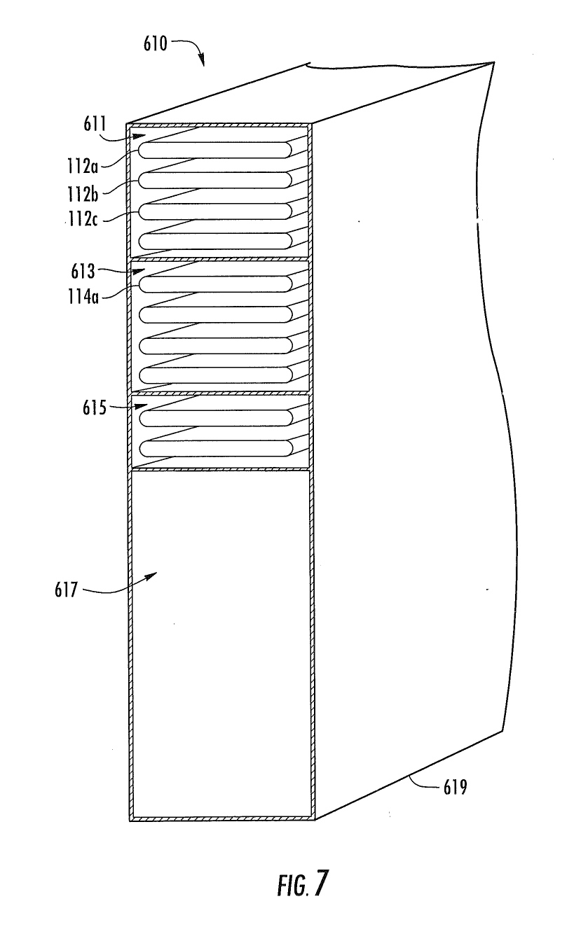

In further embodiments, a system using a multi-bus busway along the lines described above may be used with switchgear configured to be mechanically attached to the busway to provide various switching functions. For example, FIG. 8 illustrates a system 800 including UPS racks 120, bypass switch racks 130, IT racks 140 and energy storage racks 150 coupled to a busway 810 including an AC input bus 112, an AC output bus 114 and DC buses 416, similar to the arrangement shown in FIG. 4. The system 800 further includes switchgear units mechanically attached to the busway 810. The switchgear units may include, for example, switchgear units (e.g., circuit breaker assemblies) 820 configured to couple outputs of the UPS racks 120 to the AC output bus 114 and a switchgear unit (e.g., a maintenance bypass switch) 830 configured to couple the AC output bus 114 to the bypass 117. It will be appreciated that the switchgear 820, 830 may be attached to the busway 810 in various ways, such as by clamps or bolts and electrically coupled to the buses 112, 114, 416 in various ways, such as by clamps or bolts.

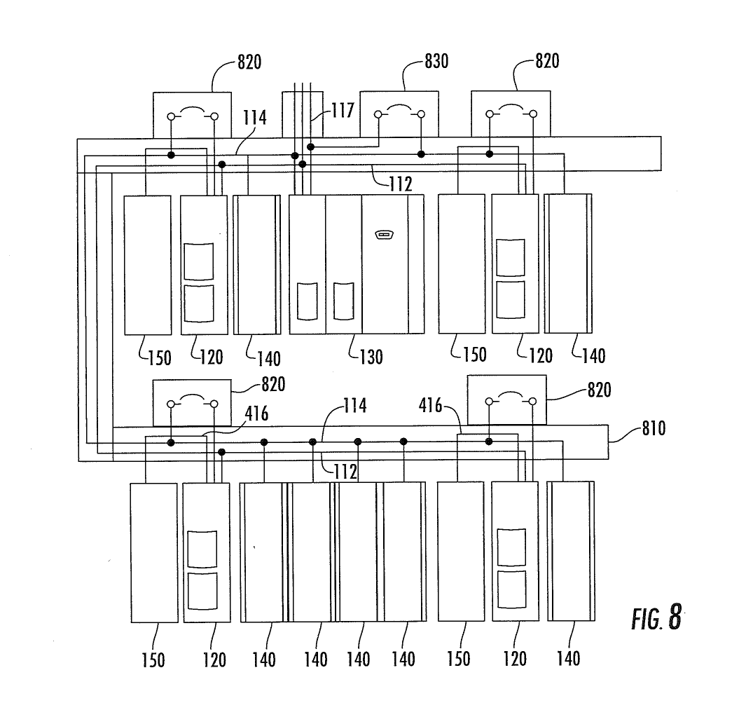

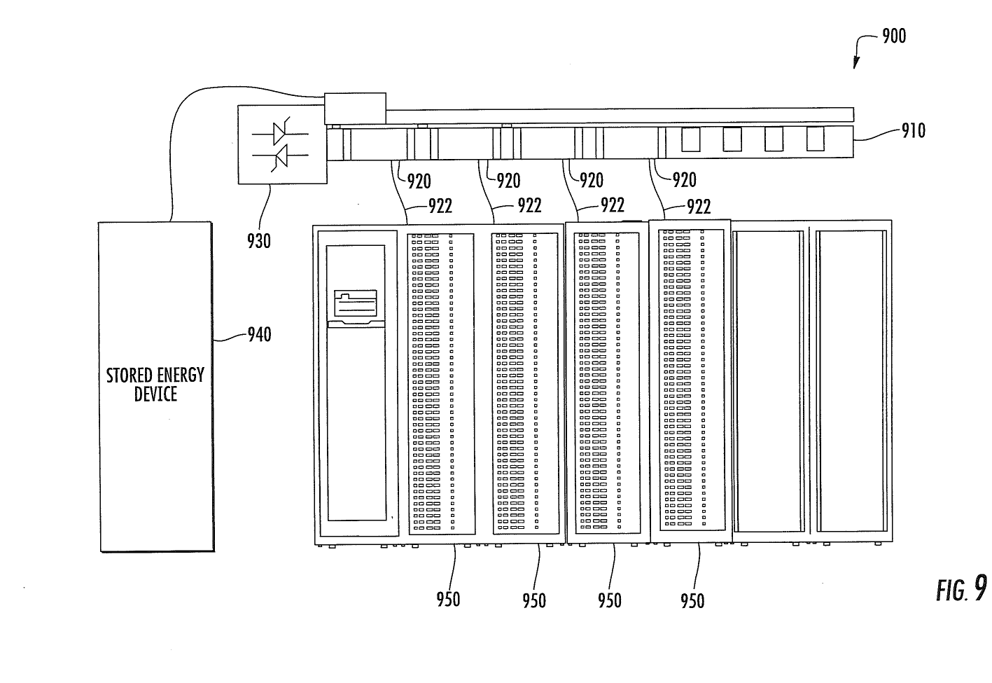

According to further embodiments of the inventive subject matter, busway assemblies along the lines described above may be used with uninterruptible power system components that are configured to be mechanically supported by the busway. For example, FIG. 9 illustrates a system 900 in which electrical equipment racks 950 are coupled to UPS bus plug units 920 mechanically supported by and electrically coupled to a busway 910. In particular, the UPS bus plug units 20 may be configured to plug into the busway 910 to engage conductors thereof in a manner similar to conventional bus plug units. The busway 910 mechanically supports the UPS bus plug units 920, which may be attached to the busway 910 in any of a variety of different ways, such as bolts or clamps. The UPS bus plug units 920 may be coupled to the racks 950 via flexible cables, which may be configured, for example, to plug into rack-mounted PDUs or similar power interfaces of the racks 950. Although FIG. 9 illustrates coupling of respective UPS bus plug units 920 to respective racks 950, in other embodiments, similar UPS bus plug units may be used to serve multiple racks and/or multiple bus plug units may serve a single rack. It will be further appreciated that connections between UPS bus plug units and racks may be provide using means other than flexible cables.

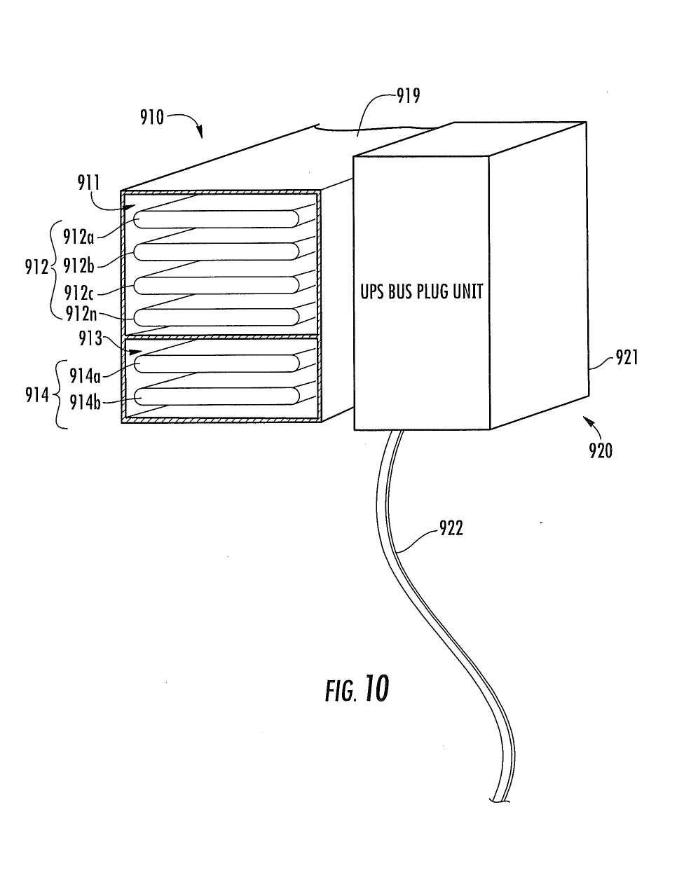

Referring to FIG. 10, the busway 910 may include at least one AC bus 912 and at least one DC bus 914. As shown, the AC bus 912 may include bus bars 912a, 912b, 912c with an accompanying neutral bus bar 912n, housed in a chamber 911 defined in a housing 919 to which a housing 921 of a UPS bus plug unit 920 may be attached. The DC bus 914 may include bus bars 914a, 914b housed in a chamber 913 of the housing 919.

The housing 921 of the UPS bus plug unit 920 may contain converter and other circuitry configured to provide UPS functionality, examples of which are described below with reference to FIGS. 11-13. As used herein, a UPS includes circuitry configured to provide power to a load via at least two power sources. For example, the at least two power sources may include a primary AC source and a DC backup source. It will be appreciated, however, that other combinations of sources and/or more than two sources may be used.

The AC bus 912 may be used to selectively couple an AC source (e.g., a utility source) to the UPS bus plug unit 920. Referring to FIG. 9, the AC bus 912 may be selectively coupled to the AC source by a solid state static switch 930, which may also be mechanically supported by the busway 910. The DC bus 914 may be coupled to an energy storage device 940, such as a battery rack, flywheel storage device, fuel cell or the like. The energy storage device 940 may be housed in a rack or cabinet having a form factor similar to that of the equipment racks 950 and positioned in a row therewith. In some embodiments, however, the energy storage device 940 may have a different form factor and/or be placed apart from the racks 950, e.g., in a different floor location or room.

The busway 910 may also provide a cooling function along the lines described above with reference to FIG. 6. For example, the busway 910 may be configured to provide a cooling air passage in fluid communication with airspaces of the UPS bus plug units 920 to allow air to be drawn through the UPS bus plug units 920 and exhausted via the busway 910. Along lines discussed above, the cooling passage of the busway may also house electrical busway and/or may be a separate air passage. In further embodiments, ducting (not shown in FIG. 9) may also be provided between the equipment racks 950 and the busway 910 to support airflow from the airspaces of the equipment racks 950 through the busway 910.

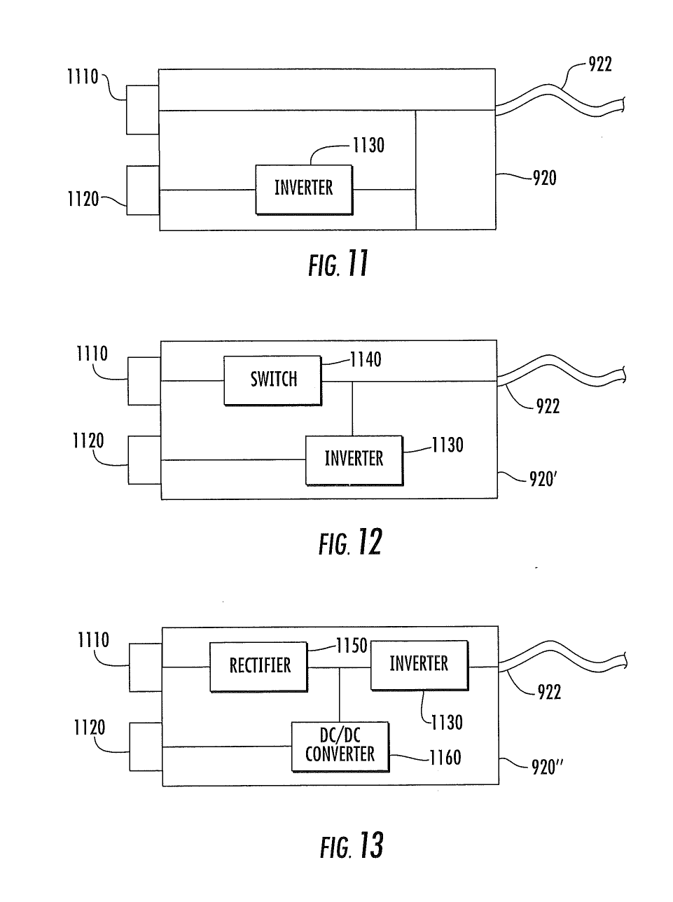

The UPS bus plug units 920 may have a variety of different configurations that support different types of UPS architectures. For example, referring to FIG. 11, a UPS bus plug unit 920 may include plug-in connectors 1110, 1120 configured to connect to the AC bus 912 and DC bus 914, respectively, of the busway 910. The UPS bus plug unit 920 may connect the AC input connector 1110 to the output cable 922 and may further include an inverter 1140 having an input coupled to the DC input connector 1120 and an output coupled to the output cable 922. The inverter 1130 of UPS plug units 920 configured in this manner may be operated in coordination with the bus-level static switch unit 930 to provide standby UPS operation, e.g., the inverter 1130 may be used to power the rack coupled to the cable 922 from the DC energy storage device 940 when the AC bus 912 is de-energized. Referring to FIG. 12, in some applications, a UPS bus plug unit 920′ may further include a switch 1140 which may be used to support standby UPS operation in a per-bus-plug-unit manner.

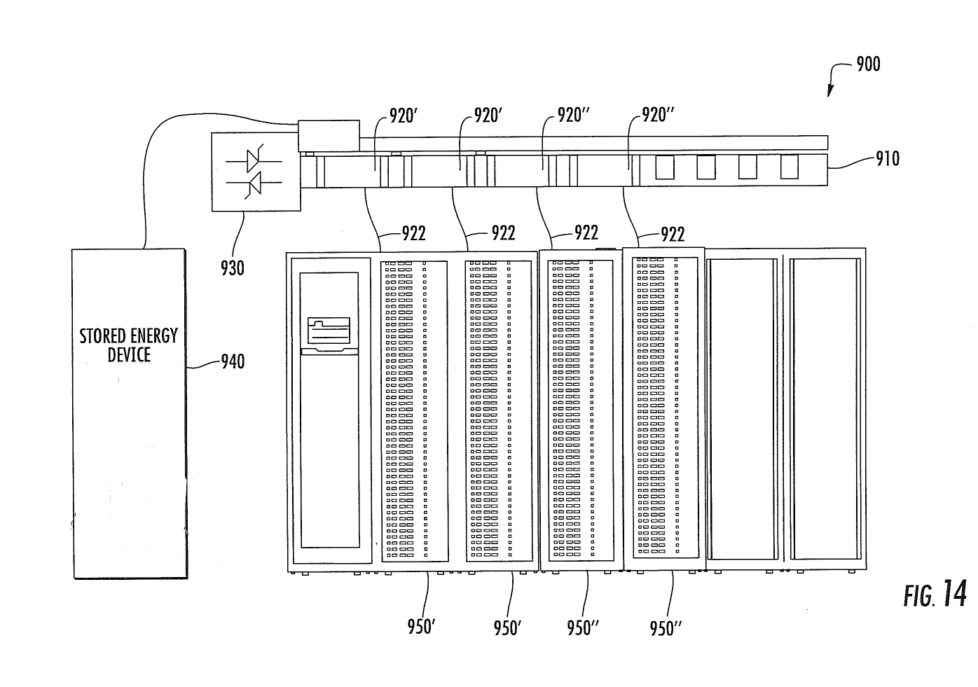

UPS bus plug units may also have other configurations. For example, FIG. 13 illustrates a UPS bus plug unit 920″ supporting double conversion UPS operation. The UPS bus plug unit 920″ includes a rectifier 1150 having an input coupled to the AC bus connector 1110 and an output coupled to the input of an inverter 1130. A DC/DC converter 1160 is coupled to the DC bus connector 1120 and to a DC link between the rectifier 1150 and the inverter 1130.

According to further embodiments shown in FIG. 14, different types of UPS bus plug units, e.g., the standby and double-conversion units 920′, 920″ described above, may be used to power different racks 950′, 950″ in a row of racks fed by a given busway 910. Thus, for example, the type of power quality protection, power distribution efficiency, etc., afforded to a given rack or group of racks may be tailored to the application supported by the rack or group of racks. It will be appreciated that FIGS. 11-13 are examples of bus plug unit configurations that may be used, and that other arrangements may be used according to the inventive subject matter. For example, a UPS bus plug unit may also include circuitry that performs filtering, circuit protection, monitoring, communications, and other functions.

In the drawings and specification, there have been disclosed exemplary embodiments of the inventive subject matter. Although specific terms are employed, they are used in a generic and descriptive sense only and not for purposes of limitation, the scope of the inventive subject matter being defined by the following claims.

That which is claimed:

1. A system comprising:
electrical equipment racks arranged in at least one row, the electrical equipment racks comprising at least one electrical equipment rack having at least one UPS therein; and
a bus duct assembly comprising an elongate housing extending along the at least one row and having electrical bus bars therein electrically coupled to the electrical equipment racks and comprising at least one AC bus bar coupled to an output of the at least one UPS and at least one DC bus bar coupled to an input of the at least one UPS.

2. The system of claim 1, wherein the electrical equipment racks comprise at least one electrical equipment rack having a power input coupled to the at least one AC bus bar.

3. The system of claim 1, wherein the electrical equipment racks comprise at least one electrical equipment rack having at least one energy storage device therein coupled to the at least one DC bus bar.

4. The system of claim 1, wherein the at least one AC bus bar comprises at least one first AC bus bar and wherein the electrical bus bars further comprise at least one second AC bus bar electrically coupled to an input of the at least one UPS.

5. The system of claim 4, wherein the electrical equipment racks comprise at least one electrical equipment rack having a static switch therein configured-to couple the at least one first AC bus bar to the at least one second AC bus bar.

6. The system of claim 4, wherein the electrical equipment racks comprise at least one electrical equipment rack having cooling equipment therein electrically coupled to the at least one second AC bus bar.

7. The system of claim 4, further comprising at least one switchgear unit mechanically attached to and supported by the housing and configured to couple the output of the at least one UPS to the at least one first AC bus bar.

8. The system of claim 4, further comprising at least one switchgear unit mechanically attached to and supported by the housing and configured to couple the at least one second AC bus bar to an AC power source.

9. The system of claim 1, further comprising at least one switchgear unit mechanically attached to and supported by the housing and configured to couple the output of the at least one UPS to the at least one AC bus bar.

10. The system of claim 1, wherein the housing has at least one air passage defined therein in fluid communication with airspaces within the electrical equipment racks and configured to support air movement therefrom.

11. A system comprising:
electrical equipment racks arranged in at least one row; and
a bus duct and cooling assembly comprising:
an elongate housing extending along the at least one row and having at least one air passage in fluid communication with airspaces within the electrical equipment racks and configured to support air movement therefrom; and
electrical bus bars in the housing and electrically coupled to the electrical equipment racks.

12. The system of claim 11, wherein the electrical bus bars are positioned inside the at least one air passage.

13. The system of claim 11, wherein the electrical bus bars are positioned in at least one chamber of the housing separate from the at least one air passage.

14. The system of claim 11, further comprising at least one air moving device in fluid communication with the at least one air passage and configured to cause air movement from the airspaces of the equipment racks through the at least one air passage.

15. The system of claim 14, wherein the at least one air moving device comprises a fan.

16. The system of claim 11, further comprising respective air passages fluidically coupling the airspaces of the electrical equipment racks to the at least one air passage.

17. The system of claim 11, wherein the bus duct system is positioned above top surfaces of the electrical equipment racks.

18. The system of claim 17, wherein the bus duct system is mounted on the top surfaces of the electrical equipment racks.

19. The system of claim 11, further comprising at least one switchgear unit mechanically attached to and supported by the housing and electrically coupled to at least one of the bus bars and to at least one of the electrical equipment racks.

20. The system of claim 19, wherein the at least one of the electrical equipment racks comprises a UPS and wherein the at least one switchgear unit is configured to couple an input and/or an output of the UPS to the at least one of the bus bars.

21. The system of claim 11:
wherein the bus bars comprise at least one AC bus bar and at least one DC bus bar; and
wherein the electrical equipment racks comprise at least one electrical equipment rack containing at least one UPS electrically coupled to the at least one AC bus bar and to the at least one DC bus bar.

22. The system of claim 21, wherein the electrical equipment racks comprise at least one electrical equipment rack containing at least one energy storage device coupled to the at least one DC bus bar.

23. A system comprising:
electrical equipment racks;
a bus duct comprising an elongate housing and electrical bus bars comprising at least one AC bus bar and at least one DC bus bar in the housing; and
at least one UPS mechanically attached to and supported by the housing and electrically coupled to the at least one AC bus bar, the at least one DC bus bar and at least one of the electrical equipment racks.

24. The system of claim 23, wherein the electrical equipment racks are arranged in at least one row and wherein the bus duct extends longitudinally along the at least one row.

25. The system of claim 24, wherein the bus duct and the at least one UPS are positioned above top surfaces of the electrical equipment racks.

26. The system of claim 24, wherein the bus duct is mechanically supported by the electrical equipment racks.

27. The system of claim 24, further comprising at least one energy storage device coupled to the at least one DC bus bar.

28. The system of claim 24, further comprising at least one static switch unit mechanically attached to and supported by the housing and electrically coupled to the at least one AC bus bar and configured to couple the at least one AC bus bar to an AC power source.

29. The system of claim 24, wherein the at least one UPS is configured as a bus plug unit pluggably coupled to the at least one AC bus bar and the at least one DC bus bar.

30. The system of claim 24, wherein the at least one UPS is coupled to the at least one of the electrical equipment racks using a flexible cable.

31. The system of claim 24, wherein the at least one UPS is a double conversion UPS or a standby UPS.

32. The system of claim 24, wherein the at least one UPS comprises a plurality of UPSs, respective ones of which have outputs coupled to respective ones of the electrical equipment racks.

33. The system of claim 32, wherein the plurality of UPSs comprises UPSs of different types.

34. A bus duct and cooling assembly comprising:
an elongate housing having at least one air passage configured to be coupled in fluid communication with airspaces within electrical equipment racks of a row of electrical equipment racks to support air movement therefrom; and
electrical bus bars in the housing and electrically coupled to the electrical equipment racks.

35. The assembly of claim 34, wherein the electrical bus bars comprise at least one AC bus bar and at least one DC bus bar.

36. The assembly of claim 34, wherein the electrical bus bars are positioned inside the at least one air passage.

37. The assembly of claim 34, wherein the electrical bus bars are positioned in at least one chamber of the housing separate from the at least one air passage.

38. An assembly comprising:
a housing configured to be mechanically mounted on a bus duct;
a UPS in the housing;
at least one first contact coupled to an DC input of the UPS and configured to be connected to at least one DC bus bar of the bus duct; and
at least one second contact coupled to an AC input of the UPS and configured to be connected to at least one AC bus bar of the bus duct.

39. The assembly of claim 38, wherein the UPS comprises a double conversion UPS or a standby UPS.
